(19) United States
(12) Patent Application Publication
(10) Pub. No.: US 2026/0304753 A1
(43) Pub. Date: Oct. 1, 2026

(54) SEMICONDUCTOR DEVICES AND FABRICATING METHODS THEREOF

(71) Applicant: Yangtze Memory Technologies Co., Ltd., Wuhan (CN)

(72) Inventors: Li Jiang, Wuhan (CN); Da Li, Wuhan (CN); Zhenyu Miao, Wuhan (CN); Na Yang, Wuhan (CN); Bin Yuan, Wuhan (CN); Wei Xu, Wuhan (CN); Wenbin Zhou, Wuhan (CN); Zongliang Huo, Wuhan (CN)

(21) Appl. No.: 19/306,715

(22) Filed: Aug. 21, 2025

Related U.S. Application Data
(63) Continuation of application No. PCT/CN2025/084660, filed on Mar. 25, 2025.

(51) Int. Cl. H10B 12/00; H10D 30/63; H10D 62/10

(52) U.S. Cl. CPC H10B 12/33; H10B 12/05; H10D 62/102; H10D 30/63

(57) ABSTRACT

A semiconductor device includes a transistor and an isolation structure. The transistor includes a semiconductor body extending along a first direction and a gate structure coupled with the semiconductor body in a second direction perpendicular to the first direction. The isolation structure is located adjacent to the semiconductor body. The isolation structure includes a first portion extending along the first direction and having at least one air gap therein and a second portion connected with a first end of the first portion along the first direction. The second portion is solid, and a size of the second portion in the reference plane is smaller than a size of the first portion in the reference plane.

### CROSS-REFERENCE TO RELATED APPLICATIONS

This application is a continuation of International Application No. PCT/CN2025/084660, filed on Mar. 25, 2025, which is hereby incorporated by reference in its entirety.

### TECHNICAL FIELD

The present disclosure generally relates to the field of semiconductor technology and, more particularly, to semiconductor devices and fabricating methods thereof.

### BACKGROUND

Planar memory cells are scaled to smaller sizes by improving process technology, circuit design, programming algorithm, and fabrication process. However, as feature sizes of the memory cells approach a lower limit, the planar process and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits to facilitate the operations of the memory array.

### SUMMARY

Some aspects of the present disclosure provide a semiconductor device including a transistor and an isolation structure. The transistor includes a semiconductor body extending along a first direction and a gate structure coupled with the semiconductor body in a second direction perpendicular to the first direction. The isolation structure is located adjacent to the semiconductor body. The isolation structure includes a first portion extending along the first direction and having at least one air gap therein and a second portion connected with a first end of the first portion along the first direction. The second portion is solid, and a size of the second portion in the reference plane is smaller than a size of the first portion in the reference plane.

In some implementations, a length of the isolation structure in the first direction is equal to or greater than a length of the gate structure in the first direction, and a length of the first portion in the first direction is equal to or greater than one half of a length of the isolation structure in the first direction.

In some implementations, a length of the at least one air gap in the first direction is equal to or greater than one half of the length of the first portion.

In some implementations, the semiconductor device further includes an interlayer dielectric layer, and a material of the second portion is different from a material of the interlayer dielectric layer.

In some implementations, a material of the first portion is different from the material of the interlayer dielectric layer.

In some implementations, the material of the interlayer dielectric layer is silicon oxide, the material of the first portion and the material of the second portion are silicon nitride.

In some implementations, gate structures of two adjacent transistors are substantially mirror symmetrical.

In some implementations, the semiconductor device further includes a storage unit coupled with the transistor in the first direction respectively.

In some implementations, the semiconductor device further includes contacts located and coupled between the transistors and the storage units.

In some implementations, a first distance between a first sidewall of the contact and a first sidewall of the semiconductor body is greater than a second distance between a second sidewall of the contact and a second sidewall of the semiconductor body. The first sidewall of the contact and the first sidewall of the semiconductor body are away from the isolation structure in a second direction perpendicular to the first direction. The second sidewall of the contact and the second sidewall of the semiconductor body are close to the isolation structure in the second direction.

Some aspects of the present disclosure provide a semiconductor device including a transistor, an isolation structure, and a source contact. The transistor includes a semiconductor body extending along a first direction and a gate structure coupled with a first side of the semiconductor body in a second direction perpendicular to the first direction. The isolation structure is located adjacent to the semiconductor body. The source contact is coupled with a source end of the semiconductor body in a reference plane perpendicular to the first direction. A first distance between a first sidewall of the contact and a first sidewall of the semiconductor body is greater than a second distance between a second sidewall of the contact and a second sidewall of the semiconductor body. The first sidewall of the contact and the first sidewall of the semiconductor body are away from the isolation structure in a second direction perpendicular to the first direction. The second sidewall of the contact and the second sidewall of the semiconductor body are close to the isolation structure in the second direction.

In some implementations, the semiconductor device further includes an interlayer dielectric layer, and a material of the isolation structure is different from a material of the interlayer dielectric layer.

In some implementations, the isolation structure includes a first portion extending along the first direction and having at least one air gap therein and a second portion connected with a first end of the first portion along the first direction. The second portion is solid, and a size of the second portion in a reference plane perpendicular to the first direction is smaller than a size of the first portion in the reference plane.

In some implementations, the semiconductor device further includes an interlayer dielectric layer and a material of the second portion is different from a material of the interlayer dielectric layer.

In some implementations, the semiconductor device a length of the isolation structure in the first direction is equal to or greater than a length of the gate structure, and a length of the first portion in the first direction is equal to or greater than one half of the isolation structure.

In some implementations, the semiconductor device the first portion includes at least one air gap, and a length of the air gap in the first direction is equal to or greater than one half of the length of the first portion.

In some implementations, the semiconductor device a projection of the contact in the reference plane covers a projection of the semiconductor body in a reference plane perpendicular to the first direction.

In some implementations, the semiconductor device a first edge of projection of the contact in a reference plane perpendicular to the first direction close to the isolation structure is overlap with a first edge of projection of the semiconductor body in the reference plane close to the isolation structure.

In some implementations, the semiconductor device gate structures of two adjacent transistors are substantially mirror symmetrical.

In some implementations, the semiconductor device a storage unit coupled with the transistor in the first direction.

Some aspects of the present disclosure provide a method for fabricating a semiconductor device, includes forming a semiconductor body extending along a first direction; forming a gate structure coupled with the semiconductor body in the first direction; and forming an isolation structure located adjacent to the semiconductor body. The isolation structure includes a first portion extending along the first direction and having at least one air gap therein and a second portion connected with a first end of the first portion along the first direction. The second portion is solid, and a size of the second portion in the reference plane is smaller than a size of the first portion in a reference plane perpendicular to the first direction.

In some implementations, forming the gate structure includes forming a gate trench adjacent to the first side of the semiconductor body; forming a gate dielectric layer covering a surface of the first side of the semiconductor body; filling the gate trench with conductive material; and forming a gate electrode layer covering the gate dielectric layer by removing extra conductive material from a backside of the semiconductor device.

In some implementations, forming the isolation structure includes forming a first isolation trench adjacent to the second side of the semiconductor body and forming a second isolation trench at a bottom of the first isolation trench. A size of the second isolation trench in the reference plane is smaller than a size of the first isolation trench in the reference plane.

In some implementations, a depth of the first isolation trench in the first direction is equal to or greater than a depth of the second isolation trench in the first direction.

In some implementations, forming the isolation structure further includes filing the second isolation trench solidly with a second dielectric material.

In some implementations, forming the isolation structure further includes filling the first isolation trench with a first dielectric material or the second dielectric material, and forming at least one air gap inside the first isolation trench, the at least one air gap is fully surrounded by the first dielectric material or the second dielectric material.

In some implementations, forming the isolation structure further includes forming an interlayer dielectric layer covering the semiconductor device, and planarizing the interlayer dielectric layer to expose a source end of the semiconductor body. The interlayer dielectric layer includes a first dielectric material, and the second isolation trench is filed by the second dielectric material.

In some implementations, the method further includes forming a source contact on the source end of the semiconductor body in the reference plane. A first side of the source contact extends beyond the first side of the semiconductor body in the reference plane, and a first distance between a first side of the source contact and a first side of the semiconductor body is greater than a second distance between a second side of the source contact and a second side of the semiconductor body.

In some implementations, forming the source contact includes forming an expanded window corresponding to the source end of the semiconductor body, and forming the source contact in the expanded window. A first side of the expanded window extends beyond the first side of the semiconductor body in the reference plane, and a first distance between a first side of the expanded window and a first side of the semiconductor body is greater than a second distance between a second side of the expanded window and a second side of the semiconductor body.

In some implementations, forming the expanded window includes etching the interlayer dielectric layer to form a recess relative to the source end of the semiconductor body; forming a first mask covering the recess and the source end of the semiconductor body; forming a second mask in the recess, a material of the second mask is different from a material of the first mask; and patterning the interlayer dielectric layer and the semiconductor body with the second mask to formed the expanded window.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a schematic circuit diagram of a semiconductor device including an array of memory cells according to some implementations of the present disclosure.

FIGS. 2A-2J each illustrates a schematic view of the semiconductor device at a certain fabricating stage of a fabricating method, according to various implementations of the present disclosure.

FIG. 3A illustrates a perspective view of a semiconductor device according to some implementations of the present disclosure.

FIG. 3B illustrates a cross-sectional view of the semiconductor device in FIG. 3A, according to some implementations of the present disclosure.

FIG. 4 illustrates a flowchart of a fabricating method for forming a semiconductor device, according to some implementations of the present disclosure.

FIGS. 5A-5L each illustrates a schematic view of the semiconductor device at a certain fabricating stage of the method shown in FIG. 4, according to various implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be used in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Vertical transistor structures are widely utilized in memory devices due to their ability to be stacked vertically, thereby enhancing memory density. The vertical configuration of memory cells effectively mitigates short-channel effects and leakage currents, improving the electrical performance of the device. It is particularly critical for boosting read/write speeds and reducing power consumption in memory applications. However, as the density of memory elements increases, the impact of parasitic capacitance on memory performance becomes more pronounced. For instance, in 3D memory architectures, word lines are vertically stacked, resulting in significantly smaller distances between adjacent word lines compared to planar memory structures. This compact arrangement leads to stronger capacitive coupling between neighboring word lines, which can adversely affect memory performance.

One effective approach to address the coupling effects between word lines involves forming air gaps within the isolation structures between transistors. The magnitude of parasitic capacitance is directly related to the dielectric constant of the material, and air, with a dielectric constant of approximately 1, is significantly lower than that of most solid materials, such as silicon oxides, which typically range from 3 to 4 or higher. By introducing air gaps between word lines, the capacitive coupling can be effectively reduced. However, incorporating air gaps introduces additional complexity to the manufacturing process, particularly in high-layer stacked 3D memory devices. The challenge lies in efficiently creating and maintaining these gaps without compromising the structural integrity or performance of the memory device.

To address one or more of the aforementioned issues, the present disclosure introduces a memory device including a semiconductor body extending along a first direction, a gate structure coupled with a first side of the semiconductor body in a second direction perpendicular to the first direction, and an isolation structure located at a second side of the semiconductor body. The second side is opposite the first side in a reference plane perpendicular to the first direction. The isolation structure includes a first portion extending along the first direction and having an air gap therein and a second portion connected with a first end of the first portion along the first direction. The second portion is solid, and a size of the second portion in the reference plane is smaller than a size of the first portion in the reference plane. This structure ensures that the air gap located within the first portion is effectively shielded by the first portion itself, preventing it from being affected by subsequent processing steps. As a result, the integrity of the air gap is preserved, avoiding any potential damage to its structure during the later stages of fabrication.

Consistent with the scope of the present disclosure, according to some implementations of the present disclosure, the semiconductor device further includes a source contact coupled with a source end of the semiconductor body in the reference plane. A first sidewall of the source contact extends beyond the first side of the semiconductor body in the first direction, and a second sidewall of the contact aligns with the second side of the semiconductor body in the first direction. In the present disclosure, based on the structure of the isolation structure, the source contact can extend toward the semiconductor body but not the isolation structure so that the effective contact area between the source contact and the semiconductor body can be increased while the leakage current increase between adjacent capacitors can be avoided by preventing the over-etching of the isolation structure.

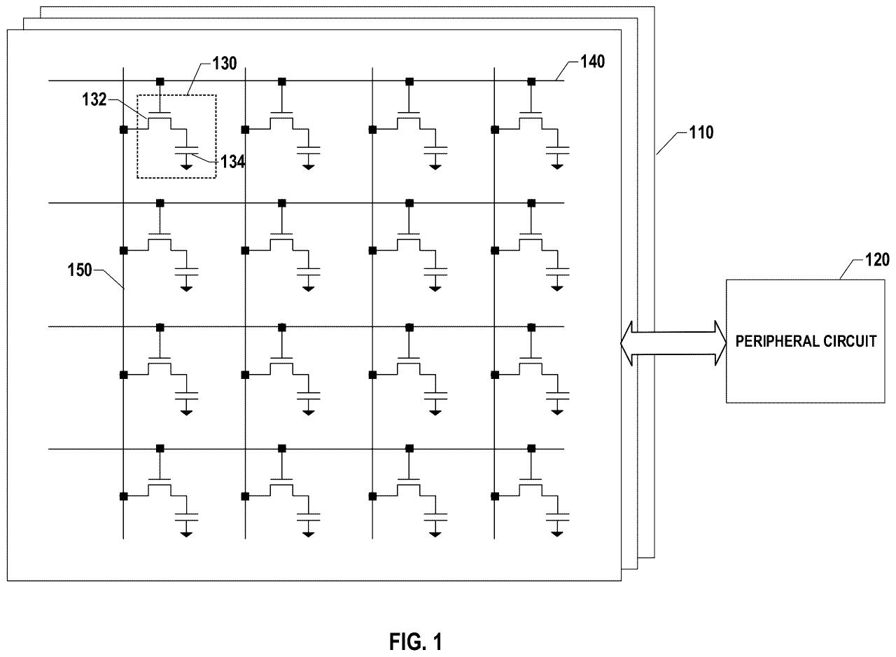

FIG. 1 illustrates a schematic diagram of a memory device 100 including peripheral circuits and an array of memory cells. Each memory cell has a vertical transistor, according to some aspects of the present disclosure. Memory device 100 can include a memory cell array 110 and peripheral circuits 120 coupled to memory cell array 110. Memory cell array 110 can be any suitable memory cell array in which each memory cell 130 includes a vertical transistor 132 and a storage unit 134 coupled to vertical transistor 132. In some implementations, memory cell array 110 is a DRAM cell array, and storage unit 134 is a capacitor for storing charge as the binary information stored by the respective DRAM cell.

As shown in FIG. 1, memory cells 130 can be arranged in a two-dimensional (2D) array having rows and columns. Memory device 100 can include word lines 140 coupling peripheral circuits 120 and memory cell array 110 for controlling the switch of vertical transistors 132 in memory cells 130 located in a row, as well as bit lines 150 coupling peripheral circuits 120 and memory cell array 110 for sending data to and/or receiving data from memory cells 130 located in a column. That is, each word line 140 is coupled to a respective row of memory cells 130, and each bit line is coupled to a respective column of memory cells 130. Consistent with the scope of the present disclosure, vertical transistors 132, such as vertical metal-oxide-semiconductor field-effect transistors (MOSFETs), can replace the conventional planar transistors as the pass transistors of memory cells 130 to reduce the area occupied by the pass transistors, the coupling capacitance, as well as the interconnect routing complexity, as described below in detail.

In some embodiments, each memory cell 130 includes a storage unit 134 for storing a bit of data as a positive or negative electrical charge as well as one or more transistors (a.k.a. pass transistors) that control (e.g., switch and selecting) access to it. In some implementations, each memory cell is a one-transistor, one-capacitor (1T1C) cell. Since transistors always leak a small amount of charge, the capacitors will slowly discharge, causing information stored in them to drain. As such, a memory cell has to be refreshed to retain data, for example, by peripheral circuit 120 coupled to the memory cell array 110, according to some implementations. In some implementations, storage unit 134 can be pillar capacitors, which are formed after forming the vertical transistors 132. Both the outer and inner surfaces of a pillar capacitor can be utilized as effective capacitor areas. This structure can be utilized to achieve greater packing density in a semiconductor device. In some other implementations, storage unit 134 can be cup capacitors, which are formed before forming the vertical transistors 132. In such implementations, the high-temperature processes of forming the cup capacitors do not affect the formation of vertical transistors 132. Thus, metal oxide semiconductors can be employed as the channel structures of vertical transistors 132.

Peripheral circuits 120 can include any suitable digital, analog, and/or mixed-signal circuits used for facilitating the operations of the memory cell array. For example, the peripheral circuits can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). Peripheral circuit 120 uses complementary metal-oxide-semiconductor (CMOS) technology, e.g., which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations. Memory device 100 can include word lines 140 coupling peripheral circuit 120 and memory cell array 110 for controlling the switch of vertical transistors 132 in memory cells 130 located in a row, as well as bit lines 150 coupling peripheral circuit 120 and memory cell array 110 for sending data to and/or receiving data from memory cells 130 located in a column. That is, each word line 140 is coupled to a respective row of memory cells 130, and each bit line 150 is coupled to a respective column of memory cells 130.

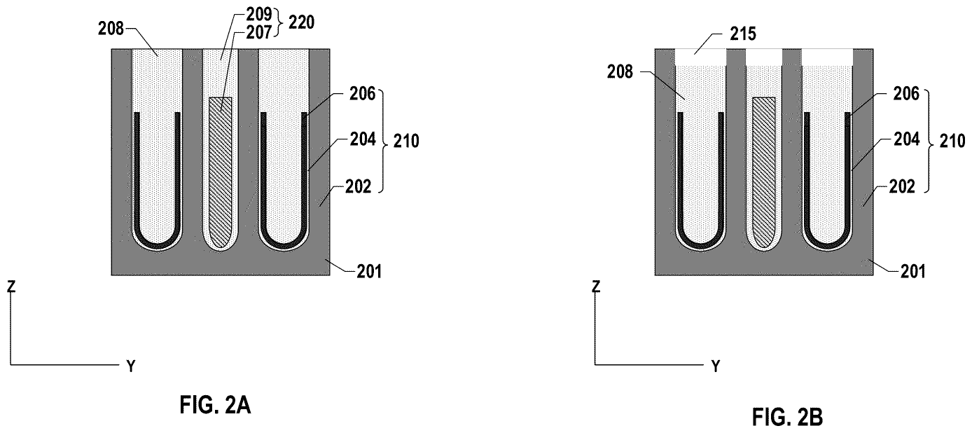

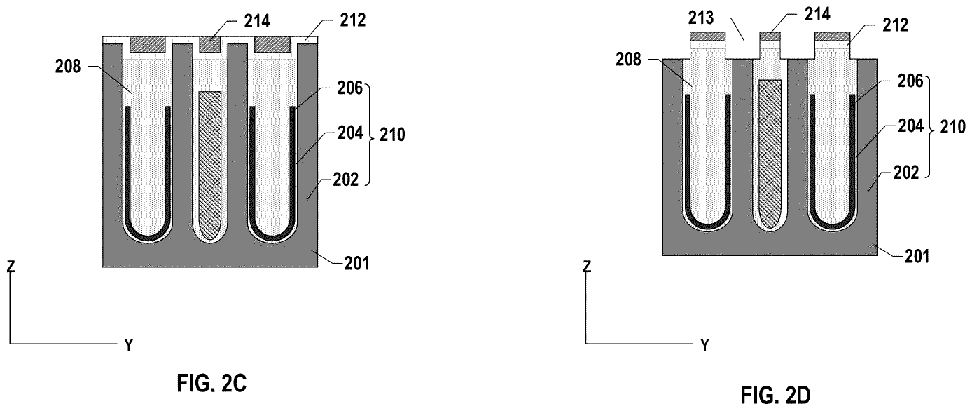

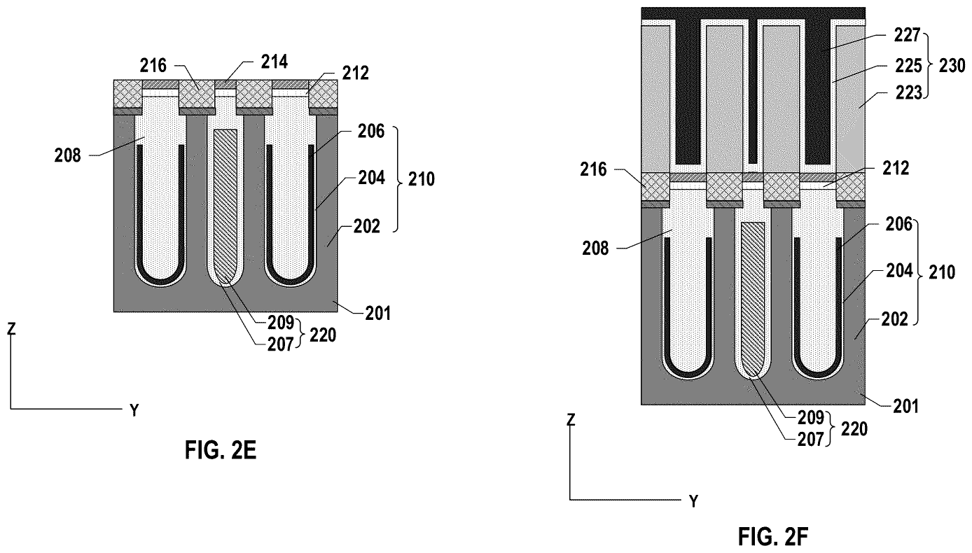

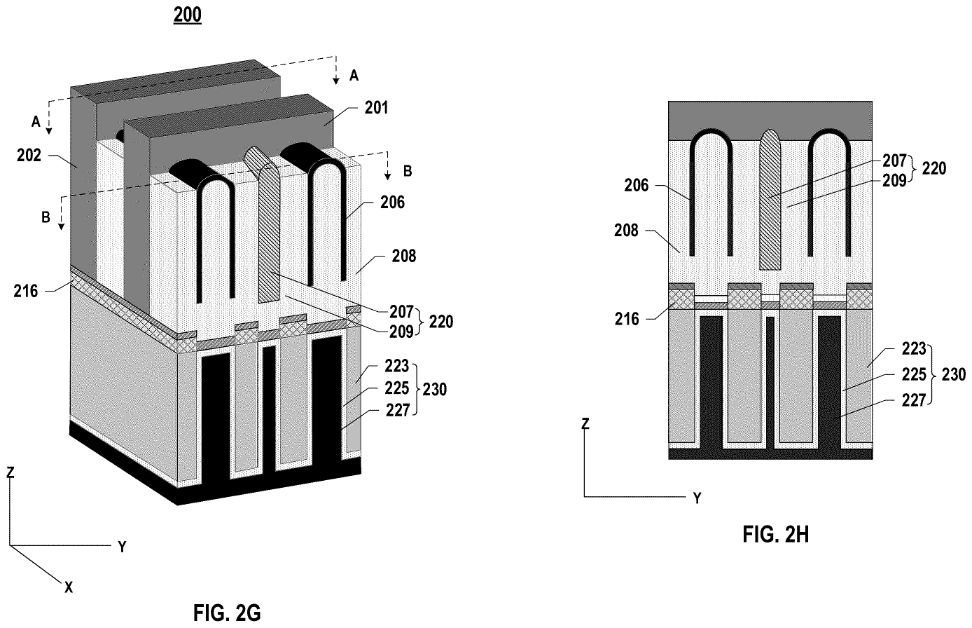

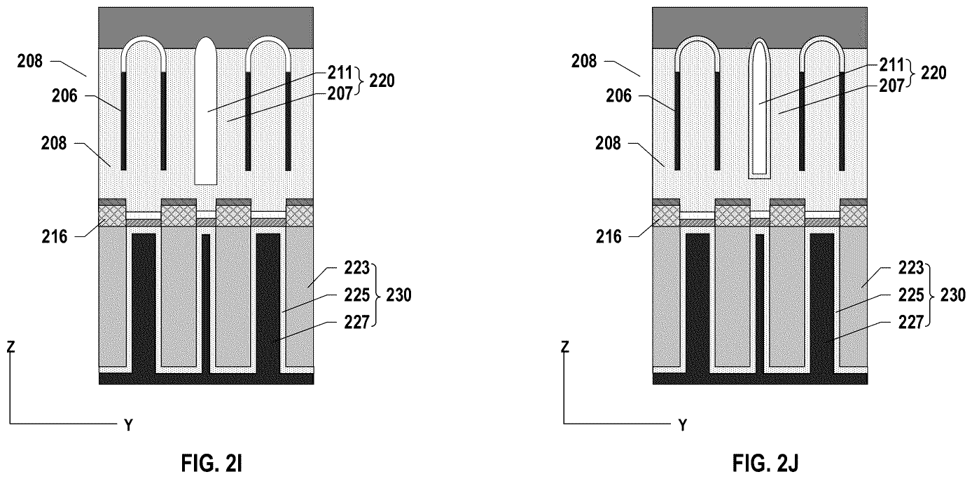

Consistent with the scope of the present disclosure, a semiconductor device 200 including a plurality of isolation structures 220 formed between adjacent vertical transistors and a fabricating method of semiconductor device 200 are provided in accordance with FIGS. 2A-2J. FIGS. 2A-2J each illustrates a schematic view of the semiconductor device at a certain fabricating stage of semiconductor device 200, according to various implementations of the present disclosure. FIG. 2A illustrates a side view of a cross-section along the y-direction of a semiconductor device 200 after vertical transistors 210 being formed, according to various implementations of the present disclosure.

In some implementations, the vertical transistors 210 disclosed herein include multi-gate transistors (e.g., gate-all-around (GAA) transistors, tri-gate transistors, or double-gate transistors), which can have a larger gate control area to achieve better channel control with a smaller subthreshold swing. During the off state, since the channel is fully depleted, the leakage current of multi-gate transistors can be significantly reduced as well. Thus, using multi-gate transistors instead of planar transistors can achieve a much better speed (saturated drain current)/leakage current performance. In some implementations, vertical transistors 210 disclosed herein include single-gate transistors (a.k.a. single-side gate transistors) in a mirror-symmetric arrangement with respect to adjacent transistors in the bit line direction as a result of splitting multi-gate transistors (e.g., double-gate transistors) using trench isolations extending along the word line direction. Thus, the memory cell density in the bit line direction can be significantly increased (e.g., doubled) without unduly complicating the fabrication process compared with using processes such as self-aligned double patterning (SADP). Also, the mirror-symmetric single-gate transistors have a larger process window for word line, bit line, and transistor pitch reduction compared to either conventional planar transistors or multi-gate vertical transistors, for example, with dual-side or all-around gates.

In some implementations, vertical transistor 210 includes a semiconductor body 202 extending vertically (in the z-direction) above substrate 201. That is, semiconductor body 202 can extend above the top surface of substrate 201 to expose not only the top surface of semiconductor body 202 but also one or more side surfaces thereof. In some implementations, semiconductor body 202 can have a cuboid shape that exposes four sides of the device. It is understood that semiconductor body 202 may have any suitable 3D shape, such as a polyhedron shape or a cylinder shape. That is, the cross-section of semiconductor body 202 in the plan view (e.g., in the x-y plane) can have a square shape, a rectangular shape (or a trapezoidal shape), a circular (or an oval shape), or any other suitable shapes. As described below with respect to the fabrication process, semiconductor body 202 can be formed from substrate 201 (e.g., by etching or epitaxy) and has the same semiconductor material (e.g., silicon crystalline silicon) as substrate 201 (e.g., a silicon substrate).

As shown in FIG. 2A, vertical transistor 210 can also include a gate structure in contact with one or more sides of semiconductor body 202, i.e., in one or more planes of the side surface(s) of the active region. In other words, the active region of vertical transistor 210, i.e., semiconductor body 202, can be at least partially surrounded by the gate structure. The gate structure can include a gate dielectric 204 over one or more sides of semiconductor body 202, e.g., in contact with four side surfaces of semiconductor body 202, as shown in FIG. 2A. The gate structure can also include a gate electrode 206 over and in contact with gate dielectric 204. Gate electrodes 206 of adjacent vertical transistors 210 can be formed in the same deposition processes and are connected with each other until being truncated. In some other implementations, gate electrodes 206 are truncated right after the deposition processes being completed. In some other implementations, gate electrodes 206 are truncated in fabricating processes at the backside of semiconductor device 200 after capacitors 230 being formed, as shown here.

Gate dielectric 204 can include any suitable dielectric materials, such as silicon oxide, silicon nitride, silicon oxynitride, or high-k dielectrics. For example, gate dielectric 204 may include silicon oxide, i.e., gate oxide. Gate electrode 206 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate electrode 206 may include doped polysilicon, i.e., a gate poly. In some implementations, gate electrode 206 includes multiple conductive layers, such as a W layer over a TiN layer. It is understood that gate electrode 206 and the word line may be a continuous conductive structure in some examples. In other words, gate electrode 206 may be viewed as part of the word line that forms the gate structure, or the word line may be viewed as the extension of gate electrode 206 to be coupled to peripheral circuits.

As shown in FIG. 2A, vertical transistor 210 can further include a pair of a source and a drain (S/D, dope regions, a.k.a., a source electrode and a drain electrode) formed at the two ends of semiconductor body 202 in the vertical direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by the gate structure in the vertical direction (the z-direction). In other words, the gate structure is formed vertically between the source and the drain. As a result, one or more channels (not shown) of vertical transistor 210 can be formed in semiconductor body 202 vertically between the source and drain when a gate voltage applied to gate electrode 206 of the gate structure is above the threshold voltage of vertical transistor 210. That is, each channel of vertical transistors 210 is also formed in the vertical direction along which semiconductor body 202 extends, according to some implementations. It is understood that the vertical transistors disclosed herein may also include single-gate transistors, double-gate transistors, tri-gate transistors, and multi-gate transistors.

As shown in FIG. 2A, semiconductor device 200 further includes a plurality of isolation structures 220, each disposed laterally between adjacent semiconductor body 202. Each isolation structure 220 can be formed in a trench extending in the word line direction (e.g., the x-direction) in parallel with gate electrode 206 to separate adjacent rows of vertical transistors 210. As described below with respect to the fabrication process, isolation structures 220 may be formed due to the relatively small pitches of the word lines in the bit line direction (e.g., the y-direction). In some implementations, isolation structure 220 includes an interior portion 207 surrounded by an isolating portion 209. Isolating portion 209 can include any suitable dielectric materials, such as silicon oxide, silicon nitride, silicon oxynitride, or high-k dielectrics. Isolating portion 209 may have the same material as interlayer dielectric layer 208, such as silicon oxide and silicon nitride. In some implementations, interior portion 207 may be formed by conductive materials and electrically connected to a common voltage potential, such as ground, to function as an electromagnetic shield. This configuration serves to reduce electrical coupling between adjacent vertical transistors 210. However, establishing and maintaining this electrical connection to a common voltage introduces significant complexity and incurs substantial manufacturing costs. In some implementations, interior portion 207 may be replaced with air during subsequent fabrication processes to create isolation structures characterized by a relatively high dielectric constant (approximately four times that of silicon oxide) at a considerably lower production cost.

FIGS. 2B-2E illustrate side views of a cross-section along the y-direction of semiconductor device 200 after storage node contact (SNC) 216 being formed in landing windows 213, according to various implementations of the present disclosure. The term “landing window” refers to the alignment region between the capacitor hole (CH) and the SNC during the manufacturing process. The size of the landing window directly impacts the quality of the connection between the capacitor hole and the storage node contact. If the landing window is too small, it may result in poor or failed connections; if it is too large, it may introduce unnecessary leakage currents. As memory device dimensions continue to shrink, existing processes require bilateral hole expansion to increase the landing window of the capacitor hole. Bilateral hole expansion enlarges the contact area of the SNC, thereby enhancing the alignment accuracy and connection reliability between the capacitor hole and the storage node contact. It is particularly critical for high-density memory devices, where alignment precision and connection quality significantly influence overall performance.

As shown in FIG. 2B, recesses 215 are formed on interlayer dielectric layer 208 and isolating portion 209 as a preparation to form SNC 216. Selective etchings can be employed to form recesses 215 without damaging semiconductor body 202. For example, dry etching techniques such as reactive ion etching (RIE) or wet etching can be utilized to selectively remove the oxide layer, creating the desired recess structure.

As illustrated in FIG. 2C, a first mask layer 212 and a second mask layer 214 are subsequently formed over the semiconductor device. First mask layer 212 and second mask layer 214 can be made of different materials, providing a relatively high etch selectivity between them. This allows for the selective etching to create a patterned mask that facilitates the expansion of the landing window. For instance, first mask layer 212 may be composed of silicon oxide, while second mask layer 214 may be made of silicon nitride. In some implementations, first mask layer 212 and second mask layer 214 can include conductive materials deposited by one or more thin film deposition processes including, but not limited to, chemical vapor deposition (CVD), physical vapor deposition (PVD), atomic layer deposition (ALD), electroplating, electroless plating, or any combination thereof. As shown in FIG. 2C, the first mask layer 212 uniformly covers the semiconductor device 200, followed by the formation of the second mask layer 214 on top of it. Subsequently, methods such as chemical mechanical polishing (CMP) are employed to thin second mask layer 214 and remove the portions of second mask layer 214 that lie outside recesses 215, resulting in a flat top surface on the semiconductor device as shown in FIG. 2C.

In some implementations, second mask layer 214 is then utilized as a hard mask in the lithography and etching processes to pattern the semiconductor device and form landing windows 213, as shown in FIG. 2D. Centered on semiconductor body 202, the dimensions of landing windows 213 are expanded in the y-direction towards both the gate structure and isolation structure 220. The extent of this expansion is determined by the thickness of the first mask layer 212, which can be adjusted as needed. For example, as shown in FIG. 2E, a dimension of the expansion portion of landing window 213 is substantially twice the thickness of the first mask layer 212.

Subsequently, SNCs 216 are formed within the landing windows 213, as illustrated in FIG. 2E. In some implementations, SNCs 216 may include conductive materials including, but not limited to, tungsten (W), cobalt (Co), copper (Cu), aluminum (Al), titanium nitride (TiN), tantalum nitride (TaN), polysilicon, silicides, or any combination thereof. In some implementations, SNCs 216 may adopt a multilayer metal or alloy structure to optimize electrical performance and thermal stability. For example, as shown in FIG. 2E, SNCs 216 may include a first layer in contact with semiconductor body 202 and a second layer positioned above the first layer. The first layer may be composed of silicide to reduce the contact resistance between the SNC 216 and the semiconductor body 202, while the second layer can be a highly conductive metal to decrease the resistance of the SNC 216 further. SNCs 216 can be deposited by one or more thin film deposition processes including, but not limited to, CVD, PVD, ALD, or any combination thereof.

As shown in FIG. 2F, capacitors 230 are formed corresponding to the vertical transistors 210. In some implementations, capacitor 230 includes a first electrode 223 above and in contact with the source or drain of vertical transistor 210. Capacitor 230 can also include a capacitor dielectric 225 above and in contact with first electrode 223 and a second electrode 227 above and in contact with capacitor dielectric 225. That is, capacitor 230 can be a vertical capacitor in which electrodes 223 and 227 and capacitor dielectric 225 are stacked vertically (in the z-direction), and capacitor dielectric 225 can be sandwiched between electrodes 223 and 227. In some implementations, each first electrode 223 is coupled to the source or drain of a respective vertical transistor 210, while all second electrodes 227 are parts of a common plate coupled to the ground, e.g., a common ground. It is understood that the structure and configuration of capacitor 230 are not limited to the example in FIG. 2F and may include any suitable structure and configuration, such as a planar capacitor, a stack capacitor, a multi-fin capacitor, a cylinder capacitor, a trench capacitor, or a substrate-plate capacitor. In some implementations, capacitor dielectric 225 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, electrodes 223 and 227 include conductive materials including, but not limited to W, Co, Cu, Al, TiN, TaN, polysilicon, silicides, or any combination thereof.

FIG. 2G illustrates a perspective view of the semiconductor device 200 after the formation of capacitors 230. In the x-direction, semiconductor bodies 202 are separated by interlayer dielectric layer 208. In some implementations, semiconductor device 200 may be flipped upside down to perform backside processing for the extraction of bit lines. Substrate 201 can be selectively removed through a patterning process, such as photolithography, followed by dry or wet etching of the dielectric materials in the dielectric layer. As shown in FIG. 2G, substrate 201 located beneath interlayer dielectric layer 208 is removed, exposing interlayer dielectric layer 208 situated between two adjacent semiconductor bodies 202. Additionally, a first end of gate electrode 206 away from capacitor 230 and a first end of interior portion 207 away from capacitor 230 are also exposed from substrate 201, as shown in FIG. 2G. In some implementations, as shown in FIGS. 2A-2H, FIGS. 2A-2F illustrate cross-sectional views of semiconductor device 200 along the AA direction in FIG. 2G, and FIG. 2H depicts a cross-sectional view of semiconductor device 200 along the BB direction in FIG. 2G.

In some implementations, after substrate 201 being patterned to expose the first end of gate electrode 206 and first end of the interior portion 207, the first end of the gate electrode 206 is removed to truncate gate electrode 206 of each vertical transistor 210 from adjacent vertical transistor 210. Interior portion 207 may also be selectively removed to create air gaps 211, as shown in FIG. 2I. Subsequently, as shown in FIG. 2J, a dielectric material is deposited over semiconductor device 200. During this process, the dielectric material inevitably infiltrates air gaps 211, resulting in a decrease in the dimensions of air gaps 211. In some implementations, air gaps 211 may be filled by a dielectric material and would have been diminished.

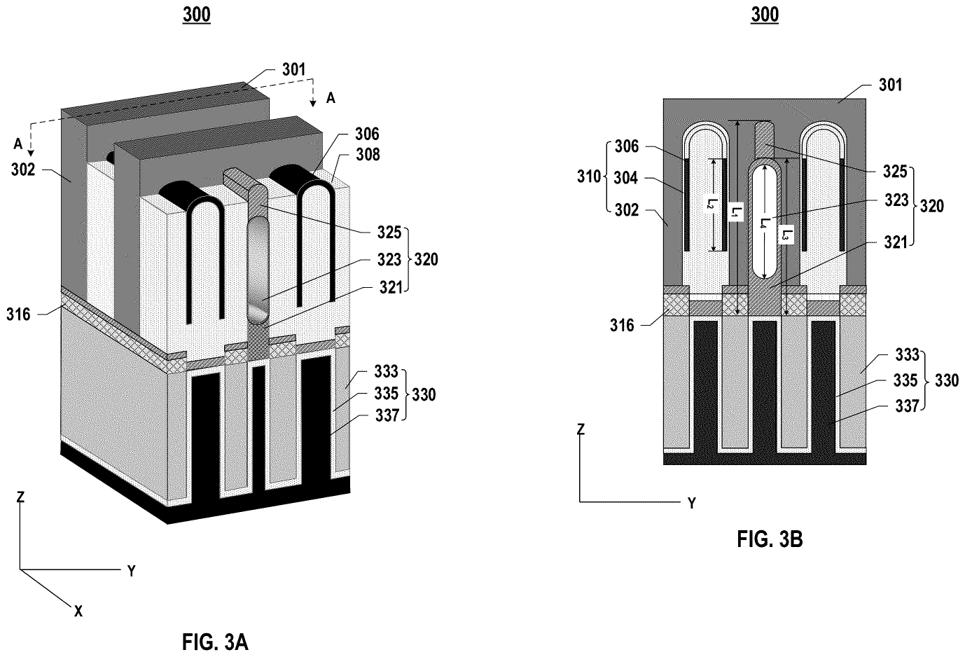

Consistent with the scope of the present disclosure, a semiconductor device 300 including a plurality of isolation structures 320 formed between adjacent vertical transistors is provided in accordance with FIG. 3A and FIG. 3B. FIG. 3A illustrates a perspective view of semiconductor device 300 before fabricating processes at the backside according to some implementations of the present disclosure. FIG. 3B illustrates a cross-sectional view of semiconductor device 300 after the fabricating processes at the backside along the AA direction in FIG. 3A, according to some implementations of the present disclosure.

In some implementations, the vertical transistors 310 disclosed herein include multi-gate transistors, such as GAA transistors, tri-gate transistors, or double-gate transistors, which can have a larger gate control area to achieve better channel control with a smaller subthreshold swing. During the off state, since the channel is fully depleted, the leakage current of multi-gate transistors can be significantly reduced as well. Thus, using multi-gate transistors instead of planar transistors can achieve a much better speed/leakage current performance. In some implementations, vertical transistors 310 disclosed herein include single-gate transistors in a mirror-symmetric arrangement with respect to adjacent transistors in the bit line direction as a result of splitting multi-gate transistors, such as double-gate transistors, using trench isolations extending along the word line direction. Thus, the memory cell density in the bit line direction can be significantly increased without unduly complicating the fabrication process compared with using processes. Also, the mirror-symmetric single-gate transistors have a larger process window for word line, bit line, and transistor pitch reduction compared to either conventional planar transistors or multi-gate vertical transistors, for example, with dual-side or all-around gates.

In some implementations, vertical transistor 310 includes a semiconductor body 302 extending vertically (in the z-direction) above substrate 301. That is, semiconductor body 302 can extend above the top surface of substrate 301 to expose not only the top surface of semiconductor body 302 but also one or more side surfaces thereof. In some implementations, semiconductor body 302 can have a cuboid shape that exposes four sides of it. It is understood that semiconductor body 302 may have any suitable 3D shape, such as a polyhedron shape or a cylinder shape. That is, the cross-section of semiconductor body 302 in the plan view (e.g., in the x-y plane) can have a square shape, a rectangular shape (or a trapezoidal shape), a circular (or an oval shape), or any other suitable shapes. As described below with respect to the fabrication process, semiconductor body 302 can be formed from substrate 301 (e.g., by etching or epitaxy) and thus, has the same semiconductor material (e.g., silicon crystalline silicon) as substrate 301 (e.g., a silicon substrate).

As shown in FIG. 3A, vertical transistor 310 can also include a gate structure in contact with one or more sides of semiconductor body 302, i.e., in one or more planes of the side surface(s) of the active region. In other words, the active region of vertical transistor 310, i.e., semiconductor body 202, can be at least partially surrounded by the gate structure. The gate structure can include a gate dielectric 204 over one or more sides of semiconductor body 202, e.g., in contact with four side surfaces of semiconductor body 202, as shown in FIG. 2A. The gate structure can also include a gate electrode 206 over and in contact with gate dielectric 204. Gate electrodes 306 of adjacent vertical transistors 310 can be formed in the same deposition processes and are connected until being truncated. In some other implementations, gate electrodes 306 are truncated right after the deposition processes being completed. In some other implementations, gate electrodes 306 are truncated in fabricating processes at the backside of semiconductor device 300 after capacitors 330 being formed, as shown here.

Gate dielectric 304 can include any suitable dielectric materials, such as silicon oxide, silicon nitride, silicon oxynitride, or high-k dielectrics. For example, gate dielectric 304 may include silicon oxide, i.e., gate oxide. Gate electrode 306 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate electrode 306 may include doped polysilicon, i.e., a gate poly. In some implementations, gate electrode 306 includes multiple conductive layers, such as a W layer over a TiN layer. It is understood that gate electrode 306 and word line may be a continuous conductive structure in some examples. In other words, gate electrode 306 may be viewed as part of the word line that forms the gate structure, or the word line may be viewed as the extension of gate electrode 306 to be coupled to peripheral circuits.

As shown in FIG. 3A, vertical transistor 310 can further include a pair of a source and a drain (S/D, dope regions, a.k.a., the source electrode and the drain electrode) formed at the two ends of semiconductor body 302 in the vertical direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by the gate structure in the vertical direction (the z-direction). In other words, the gate structure is formed vertically between the source and the drain. As a result, one or more channels (not shown) of vertical transistor 310 can be formed in semiconductor body 302 vertically between the source and drain when a gate voltage applied to gate electrode 306 of the gate structure is greater than the threshold voltage of vertical transistor 310. That is, each channel of vertical transistors 310 is also formed in the vertical direction along which semiconductor body 302 extends, according to some implementations. It is understood that the vertical transistors disclosed herein may also include single-gate transistors, double-gate transistors, tri-gate transistors, and multi-gate transistors. In some implementations, vertical transistor 310 may be single gate structures of two adjacent transistors that are substantially mirror-symmetrical, as shown in FIGS. 3A and 3B.

Semiconductor device 300 further includes capacitors 330, which correspond to the vertical transistors 310. In some implementations, capacitor 330 includes a first electrode 333 above and is in contact with the source or drain of vertical transistor 310. Capacitor 330 can also include a capacitor dielectric 335 above and in contact with first electrode 333, and a second electrode 337 above and in contact with capacitor dielectric 335. That is, capacitor 330 can be a vertical capacitor in which electrodes 333 and 337 and capacitor dielectric 335 are stacked vertically (in the z-direction), and capacitor dielectric 335 can be sandwiched between electrodes 333 and 337. In some implementations, each first electrode 333 is coupled to the source or drain of a respective vertical transistor 310, while all second electrodes 337 are parts of a common plate coupled to the ground, e.g., a common ground. It is understood that the structure and configuration of capacitor 330 are not limited to the example in FIGS. 3A and 3B, and may include any suitable structure and configuration, such as a planar capacitor, a stack capacitor, a multi-fin capacitor, a cylinder capacitor, a trench capacitor, or a substrate-plate capacitor. In some implementations, capacitor dielectric 335 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, electrodes 333 and 337 include conductive materials including, but not limited to W, Co, Cu, Al, TiN, TaN, polysilicon, silicides, or any combination thereof.

As shown in FIG. 3A, semiconductor device 300 further includes a plurality of isolation structures 320 each disposed laterally between adjacent semiconductor body 302. Each isolation structure 320 includes a first portion 321 extending along the z-direction and having an air gap 323 therein, and a second portion 325 connected with a first end of first portion 321 along the z-direction. In some implementations, the first end of first portion 321 is close to a bit line of semiconductor device 300 along the z-direction, and a second end of first portion 321 is close to capacitors of semiconductor device 300 along the z-direction. In some implementations, second portion 325 is solid, and a size of second portion 325 in the x-y plane is smaller than a size of the first portion in the x-y plane.

A length L₁ of isolation structure 320 in the z-direction is equal to or greater than a length L₂ of gate electrode 306 of the gate structure in the z-direction, and a length L₃ of first portion 321 in the z-direction is equal to or greater than one half of a length L₁ of isolation structure 320 in the z-direction. In some implementations, the length L₁ of isolation structure 320 is equal to or greater than twice the length L₃ of gate electrode 306, allowing the length L₂ of first portion 321 to be greater than or equal to the length L₃ of gate electrode 306. In some implementations, first portion 321 comprises at least one air gap 323, and a length L₄ of at least one air gap 323 in the z-direction is equal to or greater than one-half of the length L₃ of first portion 321. Since first portion 321 contains at least one air gap, and the dielectric constant of air is typically about four times the dielectric constant of dielectric materials such as silicon oxide, isolation structure 320 can maximize the isolation between two adjacent gate electrodes 306 effectively in y-direction. As a result, it significantly enhances the ability to mitigate electrical coupling between the two adjacent gate electrodes 306. It should be noted that the lengths of isolation structure 320, first portion 321, at least one air gap 323, and gate electrode 306 can be designed as needed, and the implementations are for illustrative purposes only.

Semiconductor device 300 further includes an interlayer dielectric layer 308 isolating the array of transistors 310. Interlayer dielectric layer 308 can be formed with dielectric materials including, but not limited to, silicon oxide, silicon nitride, silicon oxynitride, low-k dielectrics, or any combination thereof. In some implementations, as shown in FIG. 3A, a material of second portion 325 is different from a material of interlayer dielectric layer 308. This configuration ensures that an etch selectivity of second portion 325 is different from the etch selectivity of interlayer dielectric layer 308, so that second portion 325 will not be removed during the removing of interlayer dielectric layer 308.

In contrast to the fabrication processes described above, during the backside processing of semiconductor device 300, second portion 325 remains intact and is not subject to etching when interlayer dielectric layer 308 is removed. Second portion 325 effectively serves as a “cap” over air gap 323, preventing any additional materials from entering air gap 323 during subsequent processing steps. For instance, interlayer dielectric layer 308 may include silicon dioxide, while second portion 325 could be silicon nitride. Conversely, the interlayer dielectric layer 308 may be silicon nitride, with the second portion 325 being silicon dioxide.

In some implementations, semiconductor device 300 further includes SNCs 316 coupled with a source or drain of vertical transistors 310, as shown in FIGS. 3A and 3B. SNCs 316 may include conductive materials including, but not limited to, tungsten (W), cobalt (Co), copper (Cu), aluminum (Al), titanium nitride (TiN), tantalum nitride (TaN), polysilicon, silicides, or any combination thereof. In some implementations, SNCs 316 may adopt a multilayer metal or alloy structure to optimize electrical performance and thermal stability. For example, SNCs 316 may include a first layer in contact with semiconductor body 302 and a second layer positioned above the first layer. The first layer may be composed of silicide to reduce the contact resistance between the SNCs 316 and the semiconductor body 302, while the second layer can be a highly conductive metal to decrease the resistance of the SNCs 316 further. SNCs 316 can be deposited by one or more thin film deposition processes including, but not limited to, CVD, PVD, ALD, or any combination thereof.

A material of first portion 321 can be the same or different from the material of interlayer dielectric layer 308. In some implementations, the material of first portion 321 is different from the material of interlayer dielectric layer 308. For example, the material of interlayer dielectric layer 308 is silicon oxide, and the material of first portion 321 and the material of second portion 325 are silicon nitride, as shown in FIGS. 3A and 3B. As the etch selectivity of first portion 321 is different from the etch selectivity of interlayer dielectric layer 308, the landing windows in which SNCs 316 are formed will not be extended toward isolation structure 320. As a result, the centerline of SNCs 316 along the z-direction is misaligned with the centerline of semiconductor body 302 along the z-direction. In some implementations, a first sidewall of SNCs 316 extends beyond the first sidewall of semiconductor body 302 in the y-direction, and a second sidewall of SNCs 316 aligns with the second sidewall of semiconductor body 302 in the first direction. In some implementations, due to the limitation of the fabrication processes, the second sidewall of SNCs 316 does not precisely align with the second sidewall of semiconductor body 302 in the z-direction. In such situations, however, a first distance between a first sidewall of SNCs 316 and a first sidewall of semiconductor body 302 is greater than a second distance between a second sidewall of SNCs 316 and a second sidewall of semiconductor body 302. In semiconductor device 300, the landing window for forming the SNCs 316 is expanded solely towards gate electrode 306. As a result, the minimum distance between first electrodes 333 of adjacent capacitors 330 in semiconductor device 300 is significantly increased compared to that of adjacent capacitors 230 in the semiconductor device 200. This design effectively mitigates the increase in SNC-to-SNC leakage current that would otherwise result from an enlarged landing window.

The present disclosure further provides a method for fabricating a semiconductor device. The method includes forming a semiconductor body extending along a first direction, forming a gate structure coupled with the semiconductor body in the first direction, and forming an isolation structure located adjacent to the semiconductor body. The isolation structure includes a first portion extending along the first direction and having an air gap therein and a second portion connected with a first end of the first portion along the first direction. The second portion is solid, and a size of the second portion in the reference plane is smaller than a size of the first portion in the reference plane.

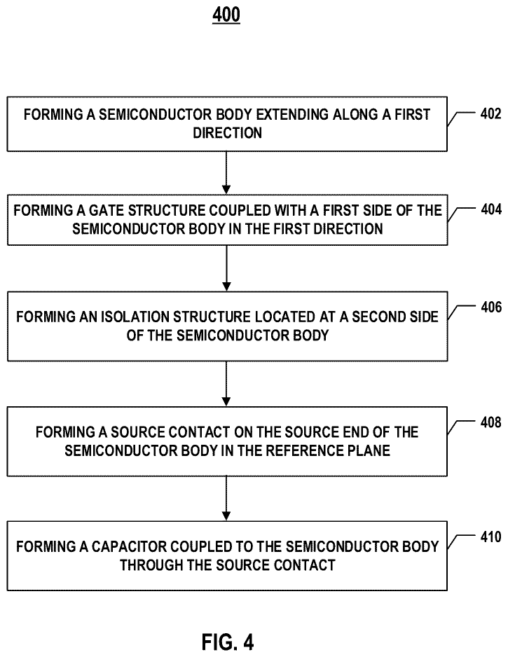

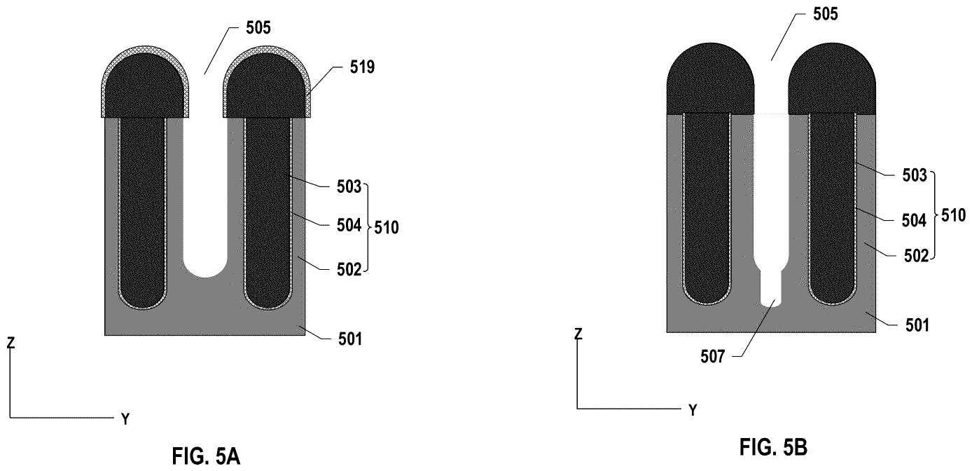

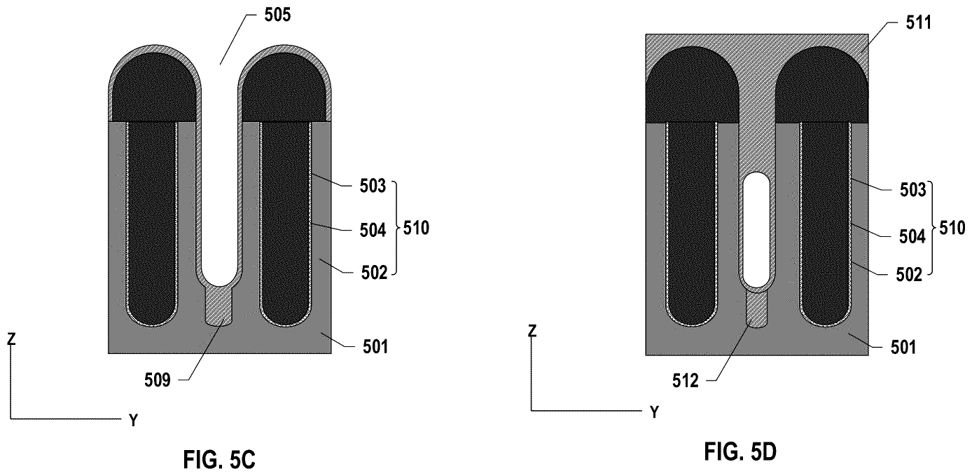

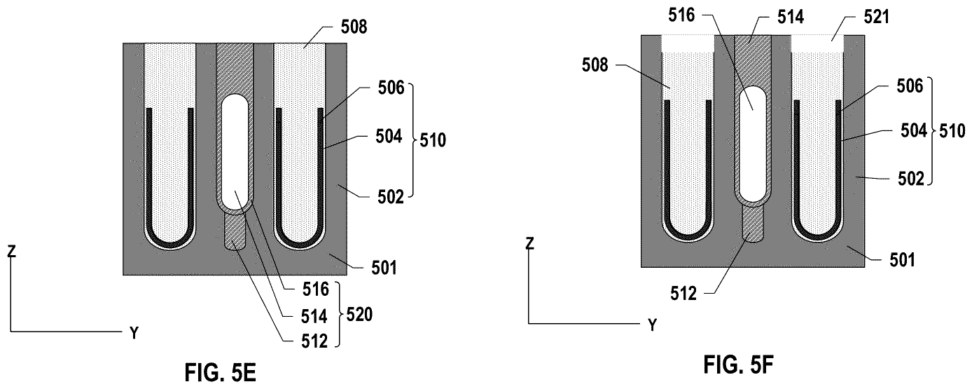

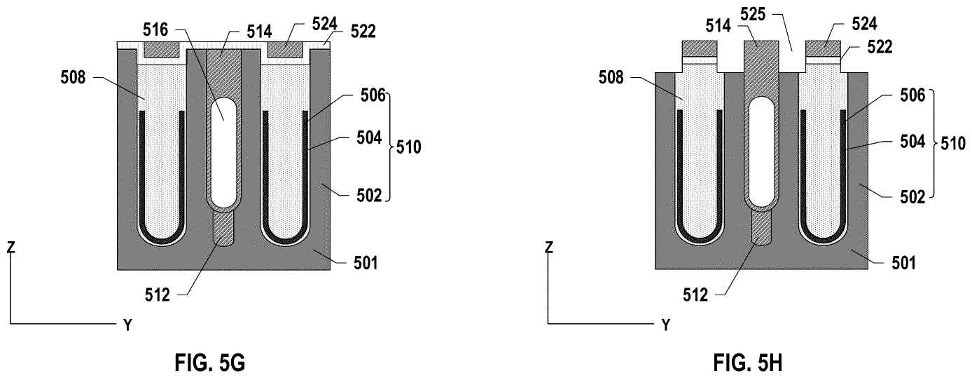

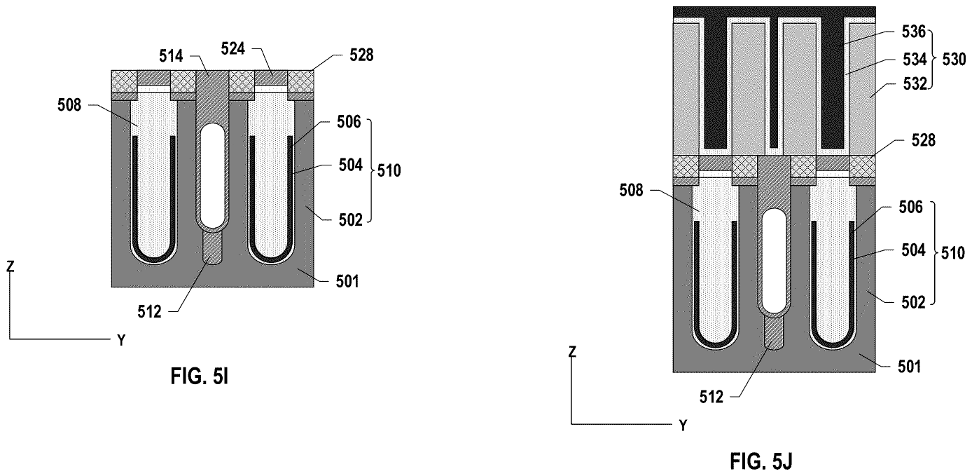

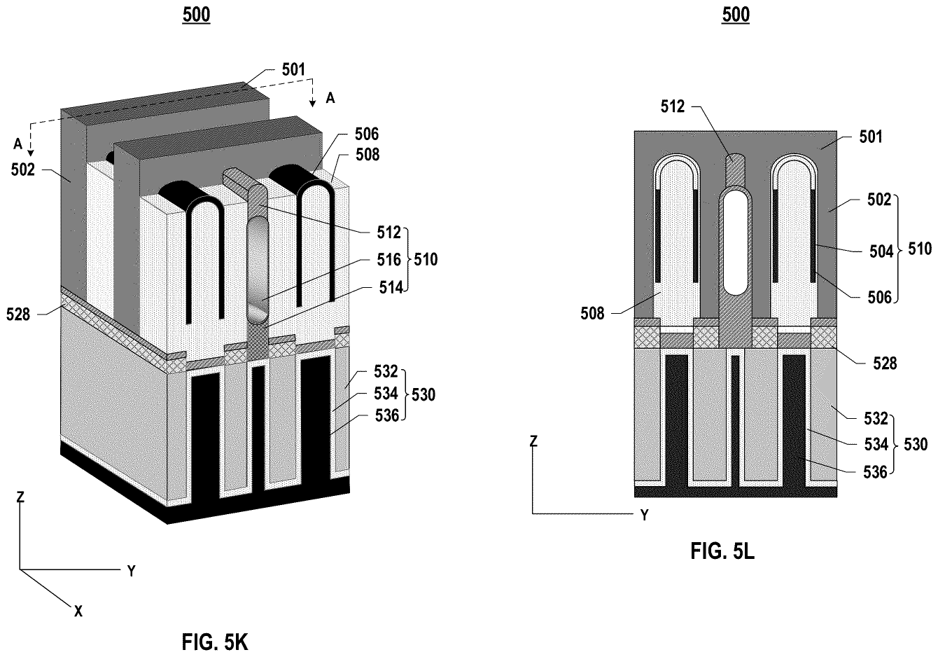

FIG. 4 illustrates a flowchart of a fabricating method 400 for forming a semiconductor device 500, according to some implementations of the present disclosure. FIGS. 5A-5L illustrate schematic views of a semiconductor device 500 at certain fabricating stages of method 400 shown in FIG. 4, according to various implementations of the present disclosure. It is understood that the operations shown in method 400 are not exhaustive and that other operations can be performed as well before, after, or between any of the illustrated operations. Further, some of the operations may be performed simultaneously or in a different order than shown in FIG. 4.

As shown in FIG. 4 and FIG. 5A, method 400 can start at operation 402, in which a semiconductor body 502 is formed extending along a z-direction from substrate 501. That is, semiconductor body 502 can extend above the top surface of substrate 501 to expose not only the top surface of semiconductor body 502, but also one or more side surfaces thereof. In some implementations, semiconductor body 502 can have a cuboid shape that exposes four sides of it. It is understood that semiconductor body 302 may have any suitable 3D shape, such as a polyhedron shape or a cylinder shape. That is, the cross-section of semiconductor body 502 in the plan view (e.g., in the x-y plane) can have a square shape, a rectangular shape (or a trapezoidal shape), a circular (or an oval shape), or any other suitable shapes. As described below with respect to the fabrication process, semiconductor body 502 can be formed from substrate 501 (e.g., by etching or epitaxy) and has the same semiconductor material (e.g., silicon crystalline silicon) as substrate 501 (e.g., a silicon substrate). In some implementations, substrate 501 can include silicon (e.g., single crystalline silicon, c-Si), silicon germanium (SiGe), gallium arsenide (GaAs), germanium (Ge), silicon-on-insulator (SOI), or any other suitable materials.

As shown in FIG. 4, method 400 can proceed to operations 404 and 406, in which a gate structure coupled with the semiconductor body 502 in the first direction and an isolation structure 520 located adjacent to semiconductor body 502 are formed. FIGS. 5A-5E illustrates schematic views of semiconductor device 500 during certain steps of the fabrication of the gate structure and isolation structure 520, according to some implementations of the present disclosure. In some implementations, the steps of operation 404 and operation 406 may be intermixed. For example, a portion of the steps from operation 404 can be performed first, followed by a portion of the steps from operation 406, alternating between the two until the fabrication of the gate structure and isolation structure 520 being complete. It is understood that the operations shown in method 400 are not exhaustive and that other operations or steps can be performed as well before, after, or between any of the illustrated operations and steps. Further, some of the operations and steps may be performed simultaneously or in a different order than shown in FIG. 4.

In some implementations, vertical transistor 510 is a single gate transistor and the gate structure of vertical transistor 510 and the isolation structure are located at two opposite sides of semiconductor body 502 in the y-direction. In a first step of operations 404 and 406, a gate trench is formed adjacent to the first side of semiconductor body 502, as shown in FIG. 5A. The gate trench is formed at the first side of each semiconductor body 502, while an isolation trench is formed on the second side of each semiconductor body 502 correspondingly. In some implementations, vertical transistor 510 may be Mirror Single-Gate (MSG) transistors. That is, gate structures of two adjacent transistors are substantially mirror-symmetrical, as shown in FIGS. 5A-5E. Since vertical transistors 510 are mirror-symmetric, the respective first sides of two adjacent vertical transistors 510 are positioned adjacent to one another, forming the trench configured to form the gate structure. Similarly, the respective second sides of the two adjacent vertical transistors 510 are also positioned adjacent to one another, creating an isolation trench configured to form the isolation structure 520.

In some implementations, during the second step of operations 404 and 406, a gate dielectric layer 504 is deposited to cover the surface of the first side of each semiconductor body 502, as illustrated in FIG. 5A. In some implementations, the formation of the gate trenches and the gate dielectric layer 504 may occur prior to the fabrication of the isolation trenches to protect the isolation trenches from damage caused by these processing steps. Subsequently, in a third step of operations 404 and 406, the gate trench is filled with a conductive material 503, as shown in FIG. 5A. In some implementations, the conductive material 503 extends outside the gate trenches and covers the semiconductor bodies 502.

In some implementations, in a fourth step of operations 404 and 406, a first isolation trench 505 is formed adjacent to the second side of semiconductor body 502, as shown in FIG. 5A. First isolation trench 505 may be formed by patterning the conductive material 503 and the semiconductor materials between two adjacent semiconductor bodies 502. First isolation trench 505 is used to form first portion 516 in subsequent fabricating processes. Therefore, in some implementations, the depth of first isolation trench 505 in the z-direction is less than the depth of the gate trench in the z-direction, ensuring that first portion 516 will not be exposed beyond interlayer dielectric layer 508 during fabricating processes from the backside. In some implementations, first isolation trench 505 can be formed by a series of patterning processes (e.g., photoetching, dry etching, wet etching, cleaning, CMP, etc.)

In some implementations, in a fifth step of operations 404 and 406, a second isolation trench 507 is formed at a bottom of first isolation trench 505. A size of second isolation trench 507 in the x-y plane is smaller than a size of first isolation trench 505 in the x-y plane, as shown in FIGS. 5A and 5B.

To form the second isolation trench 507, a hard mask 519 with a certain thickness should be created. Through selective epitaxial growth or other selective deposition processes, hard mask 519 can be made to cover only the patterned conductive material 503 and not semiconductor body 502, as illustrated in FIG. 5A. For instance, when forming hard mask 519 using CVD, the composition of the reactive gases and reaction conditions can be tailored to ensure that hard mask materials, such as silicon nitride or aluminum oxide, only deposit on the surface of conductive material 503. When forming hard mask 519 using PVD, parameters like deposition angle and pressure can be adjusted to favor deposition on conductive material 503 while limiting it on semiconductor body 502. Furthermore, prior to hard mask deposition, selective chemical treatments may be applied to the surfaces of conductive material 503 and semiconductor body 502. For example, a chemical cleaning can enhance the surface energy of conductive material 503 to improve adhesion, whereas a passivation treatment can lower the surface energy of semiconductor body 502 to reduce unwanted deposition.

Due to the blocking effect of the hard mask 519, the landing window for etching second isolation trench 507 is smaller than the landing window for etching first isolation trench 505. As a result, the dimensions of second isolation trench 507 in the x-y plane are smaller than the dimensions of first isolation trench 505 in the x-y plane, as illustrated in FIG. 5B. A sum of the depth of first isolation trench 505 and the depth of second isolation trench 507 in the z-direction is equal to or slightly larger than the depth of the gate trench in the z-direction. In some implementations, second isolation trench 507 extends beyond the gate trench in the z-direction. By controlling the thickness of hard mask 519, the dimensions of second isolation trench 507 in the x-y plane can be precisely adjusted. Hard mask 519 is removed after the formation of second isolation trench 507.

In some implementations, in a sixth step of operations 404 and 406, second isolation trench 507 is solidly filed with a second dielectric material 509 to form second portion 512, as shown in FIGS. 5C and 5D. Second dielectric material 509 is different from a first dielectric material of interlayer dielectric layer 508. This configuration ensures that an etch selectivity of second portion 512 is different from the etch selectivity of interlayer dielectric layer 508, so that second portion 512 will not be removed during the removing of interlayer dielectric layer 508. In contrast to the fabrication processes described above, during the backside processing of semiconductor device 500, second portion 512 remains intact and is not subject to etching when interlayer dielectric layer 508 is removed. Second portion 512 effectively serves as a “cap” over air gap 514, preventing any additional materials from entering air gap 514 during subsequent processing steps. For instance, interlayer dielectric layer 508 may include silicon dioxide, while second portion 512 could be silicon nitride. Conversely, the interlayer dielectric layer 508 may be silicon nitride, with the second portion 512 being silicon dioxide.

In some implementations, in a seventh step of operations 404 and 406, first isolation trench 505 is filed with dielectric material 511 to form first portion 516. Dielectric material 511 may be the same as the first dielectric material or the second dielectric material. At least one air gap 514 is formed inside first portion 516, and at least one air gap 514 is fully surrounded by dielectric material 511, as shown in FIG. 5D. Air gaps 514 may be formed due to the relatively small pitches between adjacent semiconductor bodies 502 during the filing of the first isolation trench 505. In some implementations, dielectric material 511 can be deposited along with a sacrificial layer inside dielectric material 511, and the sacrificial layer can then be removed through chemical etching or thermal treatment to form an air gap 514.

In some implementations, in a seventh step of operations 404 and 406, a gate electrode 506 covering the gate dielectric layer is formed by patterning conductive material 503 using processes like photolithography and dry/wet etch of dielectric materials in the dielectric layer. Interlayer dielectric layer 508 covering vertical transistors 510 is formed and planarized to expose a source end of semiconductor body 502, as shown in FIG. 5E.

In some implementations, method 400 can proceed to operation 408, in which an SNC 528 is formed on the source end of semiconductor body 502. FIGS. 5F-5I illustrates schematic views of semiconductor device 500 during certain steps of the fabrication of SNC 528, according to some implementations of the present disclosure.

As shown in FIG. 5F, recesses 521 are formed on interlayer dielectric layer 508 as a preparation to form SNC 528. Selective etchings can be employed to form recesses 521 without damaging semiconductor body 502. For example, dry etching techniques such as reactive ion etching (RIE) or wet etching can be utilized to selectively remove the oxide layer, creating the desired recess structure. As shown in FIG. 5F, recesses 521 are formed on interlayer dielectric layer 508 only. Isolation structure 520 is not recessed during the formation of recesses 521 because the material of first portion 516 is different from the material of interlayer dielectric layer 508.

As illustrated in FIG. 5G, a first mask layer 522 and a second mask layer 524 are subsequently formed over the semiconductor device. First mask layer 522 and second mask layer 524 can be made of different materials, providing a relatively high etch selectivity between them. This allows for the selective etching to create a patterned mask that facilitates the expansion of the landing window. For instance, first mask layer 522 may be composed of silicon oxide, while second mask layer 524 may be made of silicon nitride. In some implementations, first mask layer 522 and second mask layer 524 can include conductive materials deposited by one or more thin film deposition processes including, but not limited to, CVD, PVD, ALD, electroplating, electroless plating, or any combination thereof. As shown in FIG. 5G, the first mask layer 522 uniformly covers the semiconductor device 500, followed by the formation of the second mask layer 524 on top of it. Subsequently, methods such as CMP are employed to thin second mask layer 524 and remove the portions of second mask layer 524 that lie outside recesses 521 and resulting in a flat top surface on the semiconductor device, as shown in FIG. 5G.

In some implementations, second mask layer 524 is then utilized as a hard mask in the lithography and etching processes to pattern the semiconductor device and form landing windows 525, as shown in FIG. 2D. Unlike the expansion discussed in the fabrication process of semiconductor device 200, the dimensions of landing windows 525 are expanded in the y-direction towards the gate structure only, and isolation structure 520 will remain unetched during the expansion process. The extent of this expansion is determined by the thickness of the first mask layer 522, which can be adjusted as needed. For example, as shown in FIG. 5H, a dimension of the expansion portion of landing window 525 is substantially equal to the thickness of the first mask layer 522. As a result of the expansion, the centerline of landing window 525 along the first direction is misaligned with the centerline of semiconductor body 502 along the first direction. In some implementations, a first sidewall of landing window 525 extends beyond the first sidewall of semiconductor body 502 in the y-direction, and a second sidewall of landing window 525 aligns with the second sidewall of semiconductor body 502 in the first direction. In some implementations, due to the limitation of the fabrication processes, the second sidewall of landing window 525 does not precisely align with the second sidewall of semiconductor body 502 in the first direction. In such situations, however, a first distance between a first sidewall of landing window 525 and a first sidewall of semiconductor body 502 is greater than a second distance between a second sidewall of landing window 525 and a second sidewall of semiconductor body 502.

Subsequently, SNCs 528 are formed within the landing windows 525, as illustrated in FIG. 5I. In some implementations, a projection of SNCs 528 in the x-y plane covers a projection of semiconductor body 502 in the x-y plane. A first edge of the projection of SNCs 528 in the x-y plane overlaps with a first edge of the projection of semiconductor body 502 in the x-y plane. Both the first edge of projection of SNCs 528 and the first edge of projection of semiconductor body 502 are edges close to isolation structure 520, as shown in FIG. 5I. In some implementations, SNCs 528 is formed in landing window 525 and thus has the same shape as landing window 525. As discussed above, a centerline of SNCs 528 along the first direction is misaligned with the centerline of semiconductor body 502 along the z-direction. In some implementations, a first sidewall of SNCs 528 extends beyond the first sidewall of semiconductor body 502 in the y-direction, and a second sidewall of SNCs 528 aligns with the second sidewall of semiconductor body 502 in the z-direction. In some implementations, due to the limitation of the fabrication processes, the second sidewall of SNCs 528 does not precisely align with the second sidewall of semiconductor body 502 in the z-direction. In such situations, however, a first distance between a first sidewall of SNCs 528 and a first sidewall of semiconductor body 502 is greater than a second distance between a second sidewall of SNCs 528 and a second sidewall of semiconductor body 502.

In some implementations, SNCs 528 may include conductive materials including, but not limited to, tungsten (W), cobalt (Co), copper (Cu), aluminum (Al), titanium nitride (TiN), tantalum nitride (TaN), polysilicon, silicides, or any combination thereof. In some implementations, SNCs 528 may adopt a multilayer metal or alloy structure to optimize electrical performance and thermal stability. For example, as shown in FIG. 5I, SNCs 528 may include a first layer in contact with semiconductor body 502 and a second layer positioned above the first layer. The first layer may be composed of silicide to reduce the contact resistance between the SNC 528 and the semiconductor body 502, while the second layer can be a highly conductive metal to decrease the resistance of the SNC 528 further. SNCs 528 can be deposited by one or more thin film deposition processes including, but not limited to, CVD, PVD, ALD, or any combination thereof.

In some implementations, method 400 can proceed to operation 410, in which capacitors 530 are formed corresponding to the vertical transistors 510, as shown in FIG. 5J. In some implementations, capacitor 530 includes a first electrode 532 above and is in contact with the source or drain of vertical transistor 510. Capacitor 530 can also include a capacitor dielectric 534 above and in contact with first electrode 532, and a second electrode 536 above and in contact with capacitor dielectric 534. That is, capacitor 530 can be a vertical capacitor in which electrodes 532 and 536 and capacitor dielectric 534 are stacked vertically (in the z-direction), and capacitor dielectric 534 can be sandwiched between electrodes 532 and 536. In some implementations, each first electrode 532 is coupled to the source or drain of a respective vertical transistor 510, while all second electrodes 536 are parts of a common plate coupled to the ground, e.g., a common ground. It is understood that the structure and configuration of capacitor 530 are not limited to the example in FIG. 5J and may include any suitable structure and configuration, such as a planar capacitor, a stack capacitor, a multi-fin capacitor, a cylinder capacitor, a trench capacitor, or a substrate-plate capacitor. In some implementations, capacitor dielectric 534 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, electrodes 532 and 536 include conductive materials including, but not limited to W, Co, Cu, Al, TiN, TaN, polysilicon, silicides, or any combination thereof.

FIG. 5K illustrates a perspective view of the semiconductor device 500 after the formation of capacitors 530. In the x-direction, semiconductor bodies 502 are separated by interlayer dielectric layer 508. In some implementations, semiconductor device 500 may be flipped upside down to perform backside processing for the extraction of bit lines. Substrate 501 can be selectively removed through a patterning process, such as photolithography, followed by dry or wet etching of the dielectric materials in the dielectric layer. As shown in FIG. 5K, substrate 501 located beneath interlayer dielectric layer 508 is removed, exposing interlayer dielectric layer 508 situated between two adjacent semiconductor bodies 502. Additionally, a first end of gate electrode 506 away from capacitor 530 and second portion 512 is also exposed from substrate 501, as shown in FIG. 5K.

In some implementations, after substrate 201 being patterned to expose the first end of gate electrode 506 and second portion 512, the first end of the gate electrode 506 is removed to truncate gate electrode 506 of each vertical transistor 510 from adjacent vertical transistor 510. Because the material of second portion 512 is different from interlayer dielectric layer 508, second portion 512 will not be removed during the removal of interlayer dielectric layer 508. During the backside processing of semiconductor device 500, second portion 512 remains intact and is not subject to etching when interlayer dielectric layer 508 is removed. Second portion 512 effectively serves as a “cap” over air gaps 514, preventing any additional materials from entering air gap 514 during subsequent processing steps. For instance, interlayer dielectric layer 508 may include silicon dioxide, while second portion 512 could be silicon nitride. Conversely, the interlayer dielectric layer 508 may be silicon nitride, with the second portion 512 being silicon dioxide. It is understood that the materials of second portion 512 and interlayer dielectric layer 508 in the implementations are for illustrative purposes only and should not be explained as limits to the present disclosure. Subsequently, as shown in FIG. 5L, a dielectric material is deposited over semiconductor device 500 to function as an interlayer dielectric layer. As discussed above, air gaps 514 will be protected from subsequent processes by second portion 512 of isolation structure 520.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described implementations but should be defined only in accordance with the following claims and their equivalents.

What is claimed is:

1. A semiconductor device comprising:
a transistor comprising:
a semiconductor body extending along a first direction; and
a gate structure coupled with the semiconductor body in a second direction perpendicular to the first direction; and
an isolation structure located adjacent to the semiconductor body,
wherein the isolation structure comprises:
a first portion extending along the first direction and having at least one air gap therein; and
a second portion connected with a first end of the first portion along the first direction, wherein the second portion is solid, and a size of the second portion in a reference plane perpendicular to the first direction is smaller than a size of the first portion in the reference plane.

2. The semiconductor device of claim 1, wherein
a length of the isolation structure in the first direction is equal to or greater than a length of the gate structure in the first direction; and
a length of the first portion in the first direction is equal to or greater than one half of a length of the isolation structure in the first direction.

3. The semiconductor device of claim 2, wherein a length of the at least one air gap in the first direction is equal to or greater than one half of the length of the first portion.

4. The semiconductor device of claim 1, further comprising an interlayer dielectric layer, wherein a material of the second portion is different from a material of the interlayer dielectric layer.

5. The semiconductor device of claim 4, wherein a material of the first portion is different from the material of the interlayer dielectric layer.

6. The semiconductor device of claim 5, wherein the material of the interlayer dielectric layer is silicon oxide, the material of the first portion and the material of the second portion are silicon nitride.

7. The semiconductor device of claim 1, wherein gate structures of two adjacent transistors are substantially mirror symmetrical.

8. The semiconductor device of claim 1, further comprising a storage unit coupled with the transistor in the first direction respectively.

9. The semiconductor device of claim 8, further comprising a source contact located and coupled between the transistor and the storage unit correspondingly.

10. The semiconductor device of claim 9, wherein
a first distance between a first sidewall of the source contact and a first sidewall of the semiconductor body is greater than a second distance between a second sidewall of the source contact and a second sidewall of the semiconductor body;
the first sidewall of the source contact and the first sidewall of the semiconductor body are away from the isolation structure in a second direction perpendicular to the first direction; and
the second sidewall of the source contact and the second sidewall of the semiconductor body are close to the isolation structure in the second direction.

11. A semiconductor device comprising:
a transistor comprising:
a semiconductor body extending along a first direction; and
a gate structure coupled with a first side of the semiconductor body in a second direction perpendicular to the first direction;
an isolation structure located adjacent to the semiconductor body; and
a source contact coupled with a source end of the semiconductor body,
wherein a first distance between a first sidewall of the source contact and a first sidewall of the semiconductor body is greater than a second distance between a second sidewall of the source contact and a second sidewall of the semiconductor body;
the first sidewall of the source contact and the first sidewall of the semiconductor body are away from the isolation structure in a second direction perpendicular to the first direction; and
the second sidewall of the source contact and the second sidewall of the semiconductor body are close to the isolation structure in the second direction.

12. The semiconductor device of claim 11, wherein a projection of the source contact in a reference plane perpendicular to the first direction covers a projection of the semiconductor body in a reference plane perpendicular to the first direction.

13. A method for fabricating a semiconductor device, comprising:
forming a semiconductor body extending along a first direction;
forming a gate structure coupled with the semiconductor body in the first direction; and
forming an isolation structure located adjacent to the semiconductor body,
wherein the isolation structure comprises a first portion extending along the first direction and having at least one air gap therein, and a second portion located under the first portion; and
the second portion is solid, and a size of the second portion in a reference plane perpendicular to the first direction is smaller than a size of the first portion in a reference plane perpendicular to the first direction.

14. The method of claim 13, wherein forming the gate structure comprises:
forming a gate trench adjacent to a first side of the semiconductor body;
forming a gate dielectric layer covering a surface of the first side of the semiconductor body;
filling the gate trench with conductive material; and
forming a gate electrode layer covering the gate dielectric layer by removing extra conductive material from a backside of the semiconductor device.

15. The method of claim 13, wherein forming the isolation structure comprises:
forming a first isolation trench adjacent to a second side of the semiconductor body; and
forming a second isolation trench at a bottom of the first isolation trench,
wherein a size of the second isolation trench in the reference plane is smaller than a size of the first isolation trench in the reference plane.

16. The method of claim 15, wherein forming the isolation structure further comprises:
filing the second isolation trench solidly with a second dielectric material;
filling the first isolation trench with a first dielectric material or the second dielectric material; and
forming at least one air gap inside the first isolation trench, the at least one air gap is fully surrounded by the first dielectric material or the second dielectric material.

17. The method of claim 16, wherein forming the isolation structure further comprises:
forming an interlayer dielectric layer covering the semiconductor device; and
planarizing the interlayer dielectric layer to expose a source end of the semiconductor body,
wherein the interlayer dielectric layer comprises a first dielectric material; and
the second isolation trench is filled with the second dielectric material.

18. The method of claim 17, further comprising forming a source contact on the source end of the semiconductor body,
wherein a first side of the source contact extends beyond the first side of the semiconductor body in the reference plane; and
a first distance between a first side of the source contact and a first side of the semiconductor body is greater than a second distance between a second side of the source contact and a second side of the semiconductor body.

19. The method of claim 18, wherein forming the source contact comprises:
forming an expanded window corresponding to the source end of the semiconductor body; and
forming the source contact in the expanded window,
wherein a first side of the expanded window extends beyond the first side of the semiconductor body in the reference plane; and
a first distance between a first side of the expanded window and a first side of the semiconductor body is greater than a second distance between a second side of the expanded window and a second side of the semiconductor body.

20. The method of claim 19, wherein forming the expanded window comprises:
etching the interlayer dielectric layer to form a recess relative to the source end of the semiconductor body;
forming a first mask covering the recess and the source end of the semiconductor body;
forming a second mask in the recess, a material of the second mask is different from a material of the first mask; and
patterning the interlayer dielectric layer and the semiconductor body with the second mask to form the expanded window.
